(19) United States
(12) Patent Application Publication
(10) Pub. No.: US 2019/0098749 A1
(43) Pub. Date: Mar. 28, 2019

(54) BOARD, ELECTRIC DEVICE, AND METHOD OF DETERMINING BOARD

(71) Applicant: SHARP KABUSHIKI KAISHA, Osaka (JP)

(72) Inventor: NORIHISA SHINTANI, Sakai City (JP)

(21) Appl. No.: 16/141,822

(22) Filed: Sep. 25, 2018

(30) Foreign Application Priority Data
Sep. 26, 2017 (JP) 2017-184383

(51) Int. Cl. H05K 1/02; H05K 1/18; H05K 3/00; G02F 1/13

(52) U.S. Cl. CPC H05K 1/0268; H05K 1/189; H05K 2203/162; G02F 1/1309; H05K 2201/10136; H05K 3/0044

(57) ABSTRACT

A board includes a board main body portion, a removable portion that is removably continuous from the board main body portion via a weak portion having strength lower than a surrounding portion thereof, and a line having two end portions in a linear direction on the board main body portion and a portion between the two end portions on the removable portion.

### CROSS REFERENCE TO RELATED APPLICATION

This application claims priority from Japanese Patent Application No. 2017-184383 filed on Sep. 26, 2017. The entire contents of the priority application are incorporated herein by reference.

### TECHNICAL FIELD

The present technology relates to aboard, an electric device, and a method of determining a board.

### BACKGROUND

There has been known a display device (an electric device) including a display panel (a liquid crystal panel) and a board that is electrically connected to the display panel. An example of such a display device is disclosed in Japanese Unexamined Patent Application Publication No. 2010-139770.

In a process of producing an electric device, a specific treatment such as a rework treatment may be performed for some of the mass produced electric devices. It is demanded to distinguish electric devices that have been subjected to the special treatment from other electric devices. Boards of the electric devices that have been subjected to the special treatment are marked and the marking is checked in a succeeding process to identify the boards (or the electric devices). However, in the method of identifying a board with the marking, a process of checking the marking visually is required. Another component may be mounted on the board of some type of electric devices. In such a type of devices, the marking may be covered with the other component and the marking cannot be visually seen.

### SUMMARY

The technology described herein was made in view of the above circumstances. An object is to identify a board without performing visual checking.

To solve the above problem, a board includes a board main body portion, a removable portion that is removably continuous from the board main body portion via a weak portion having strength lower than a surrounding portion thereof, and a line having two end portions in a linear direction on the board main body portion and a portion between the two end portions on the removable portion.

In the above configuration, if a voltage is applied to the two end portions of the line, a current flows through the line. If the removable portion is separated from the board main body portion, a part of the line is removed from the line and the line is disconnected. With such a configuration, if a voltage is applied to the two end portions of the line, current does not flow through the line. Therefore, a current flowing through the line is measured by applying a voltage to the two end portions of the line, and it is determined whether the removable portion is separated or not. Based on the determination whether or not the removable portion is separated, the boards are distinguished between the certain boards (from which the removable portion is not separated) and the boards (from which the removable portion is separated). According to the above configuration, the separation of the removable portion is not checked visually and therefore, determination accuracy is improved. Even if the removable portion is covered with another component, it can be determined whether the removable portion is separated or not. Furthermore, the removable portion that is continuous from the board main body portion with the weak portions can be easily separated by hand.

To solve the above problem, an electric device includes the above-described board, and an electric component, and the board main body portion includes an electric component, line that is electrically connected to the electric component, and the electric component line has an end portion opposite from the electric component and the end portion of the electric component line and two end portions of the line are disposed on a peripheral edge portion of the board main body portion. In the checking process of checking the electric component, a voltage is applied to the end portions of the line at the same time of applying a voltage to the end portion of the electric component line and it is determined whether the removable portion is separated or not.

To solve the above problem, a method of determining a certain board includes a separation process of breaking a weak portion of the certain board and separating a removable portion from a board main body portion of the certain board, the removable portion being removably continuous from the board main body portion via the weak portion having strength lower than a surrounding portion thereof, the board main body portion having two end portions of a line in a linear direction thereof, and the removable portion having a part of the line between the two end portions, and a determining process of determining whether the removable portion is separated or not by applying a voltage to the two end portions of the line of the certain board.

In a configuration that the removable portion is separated, a part of the line is removed and the line is disconnected. In such a configuration, if a voltage is applied to the two end portions of the line, current does not flow through the line. Therefore, it is determined whether the removable portion is separated or not by applying a voltage to the two end portions of the line. Based on the determination whether or not the removable portion is separated, the boards are distinguished between the certain boards (from which the removable portion is not separated) and the boards (from which the removable portion is separated). According to the above method, the separation of the removable portion is not checked visually and therefore, determination accuracy is improved. Even if the removable portion is covered with another component, it can be determined whether the removable portion is separated or not. Furthermore, the removable portion that is continuous from the board main body portion with the weak portions can be easily separated by hand.

According to the technology described herein, a board can be identified without performing visual checking.

### BRIEF DESCRIPTION OF THE DRAWINGS

FIG. 1 is a perspective view illustrating a liquid crystal display device according to a first embodiment.

FIG. 2 is a plan view illustrating a flexible circuit board included in the liquid crystal display device.

FIG. 3 is a plan view illustrating the flexible circuit board from which a removable portion is separated.

FIG. 4 is a plan view illustrating a flexible circuit board according to a second embodiment.

FIG. 5 is a plan view illustrating a flexible circuit board according to a third embodiment.

### DETAILED DESCRIPTION

### First Embodiment

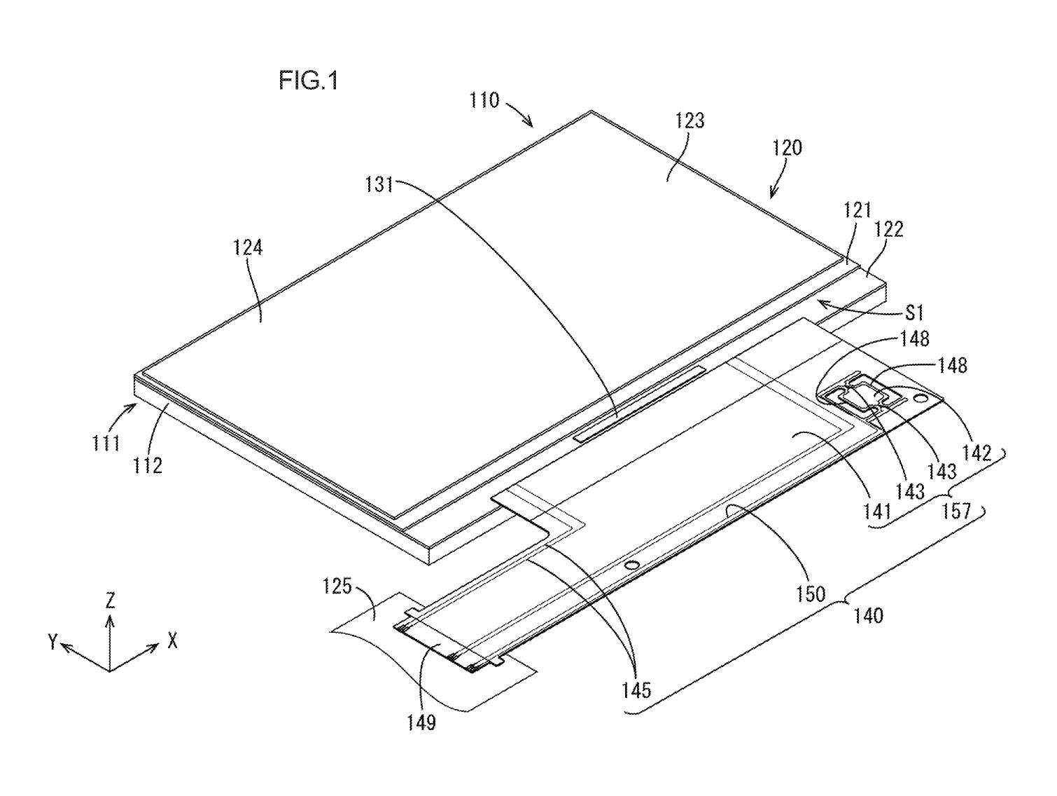

A first embodiment of the technology described herein will be described with reference to FIGS. 1 to 3. X-axis, Y-axis and Z-axis may be present in the drawings and each of the axial directions represents a direction represented in each drawing. As illustrated in FIG. 1, a liquid crystal display device 110 (a display device, an electric device) includes a liquid crystal panel 120 (a display panel, an electric component), a backlight unit 111 that is an external light source and supplies light to the liquid crystal panel 120, and a flexible circuit board 140 that is connected to the liquid crystal panel 120. The backlight unit 111 is disposed on a back side of the liquid crystal panel 120 and includes a chassis 112 and a light source (not illustrated) arranged within the chassis 112. Cold cathode tubes, LEDs, and organic ELs may be used as the light source.

As illustrated in FIG. 1, the liquid crystal panel 120 has a laterality-long square (rectangular) shape as a whole. The liquid crystal panel 120 includes a display surface 123 displaying images thereon. The liquid crystal panel 120 includes a pair of substrates 121, 122 that are opposite each other and a liquid crystal layer (not illustrated) between the substrates 121, 122. The liquid crystal layer includes liquid crystal molecules having optical characteristics that vary according to application of electric field. The substrates 121, 122 include a counter substrate 121 on the front and an array substrate 122 (an active matrix substrate, a component substrate, a TFT substrate) on a back side (a rear surface side). Each of the counter substrate 121 and the array substrate 122 includes a glass substrate made of glass and various types of films layered on an inner surface of the glass substrate. Polarizing plates 124 are bonded to outer surfaces of the substrates 121, 122, respectively (a polarizing plate on the substrate 122 is not illustrated).

As illustrated in FIG. 1, the array substrate 122 includes a non-overlapping section S1 at one of peripheral edge portions of a surface thereof with respect to a short-side direction and the counter substrate 121 does not overlap the non-overlapping section S1. The non-overlapping section S1 (the peripheral edge portion of the display panel) has an elongated shape elongated in the X-axis direction. A driver 131 (a display driving section) is mounted on the non-overlapping section S1. The driver 131 is arranged such that an elongated direction thereof matches the X-axis direction. A flexible circuit board 140 (a board) is arranged on the non-overlapping section S1 of the array substrate 122.

One edge portion of the flexible circuit board 140 is electrically connected to the driver 131 via wiring (not illustrated) that is formed on the array substrate 122. Another edge portion of the flexible circuit board 140 is connected to a control board 125. The control board 125 supplies signals to the driver 131 through the flexible circuit board 140 and controls driving of the driver 131 to drive switching components such as TFTs disposed on the array substrate 122 of the liquid crystal panel 120 and display images on the display surface 123. The flexible circuit board 140 may be folded toward a back surface of the chassis 112. FIG. 1 illustrates the flexible circuit board 140 before being folded.

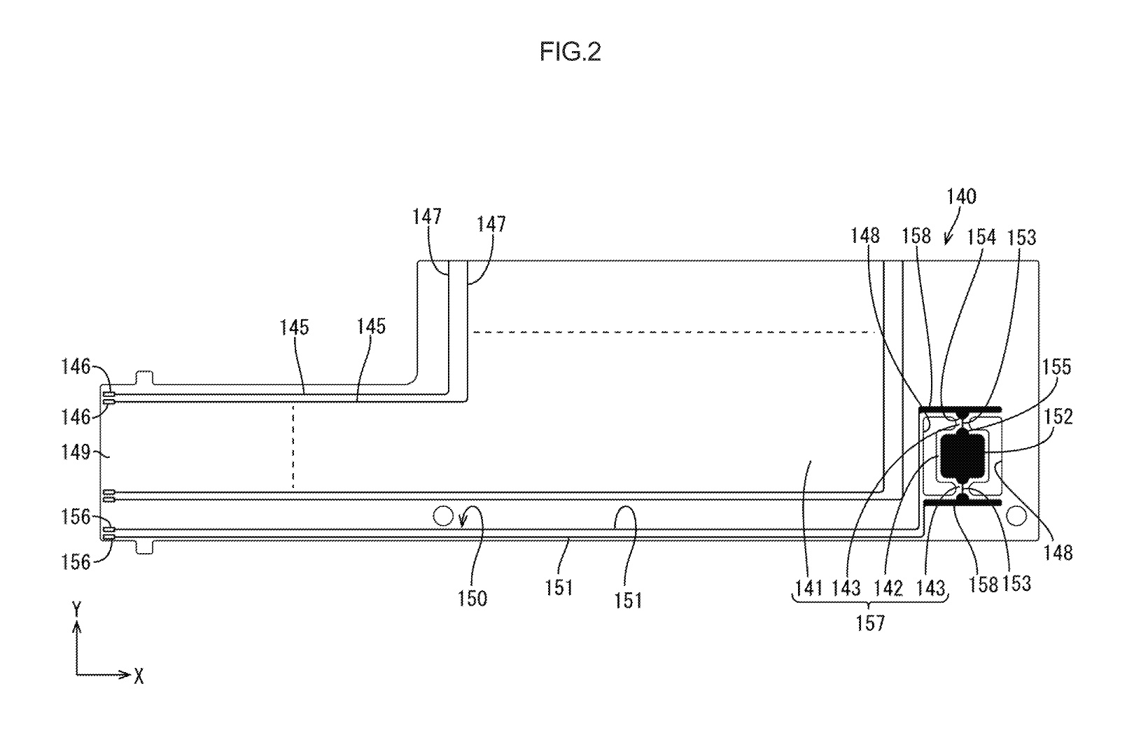

As illustrated in FIG. 1, the flexible circuit board 140 includes a plate member 157, a line 150, and liquid crystal panel lines 145. As illustrated in FIG. 2, the plate member 157 includes a board main body portion 141, a removable portion 142, and a pair of weak portions 143, 143. The board main body portion 141 has an elongated plate shape elongated in the X-axis direction. The removable portion 142 is continuous from the board main body portion 141 so as to be separable therefrom. The weak portions 143 connect the board main body portion 141 and the removable portion 142. More specifically, the board main body portion 141, the removable portion 142, and a pair of weak portions 143, 143 are formed by forming two slits 148, 148 in one plate member 157. Each of the two slits 148, 148 is formed in a U-shape and the two slits 148 are arranged opposite each other in the X-axis direction such that ends of the respective slits 148 are next to each other in an extending direction of the slits 143. Parts of the plate member 157 between the ends of the two slits 148 in the extending direction are the weak portions 143, 143. A portion of the plate member 157 other than the removable portion 142 and the pair of weak portions 143, 143 is the board main body portion 141.

It is determined whether the removable portion 142 is separated or not (which will be described later) through the line 150 (a board identifying line). The liquid crystal panel lines 145 (electric component lines) electrically connect the liquid crystal panel 120 and the control board 125 and are disposed on the board main body portion 141. As illustrated in FIG. 2, the liquid crystal panel lines 145 extend in an L-shape and are arranged at a certain interval. One end portions 146 of the respective liquid crystal panel lines 145 are connected to the control board 125 (see FIG. 1) and another ends 147 thereof are connected to the liquid crystal panel 120 (mainly to the driver 131, see FIG. 1).

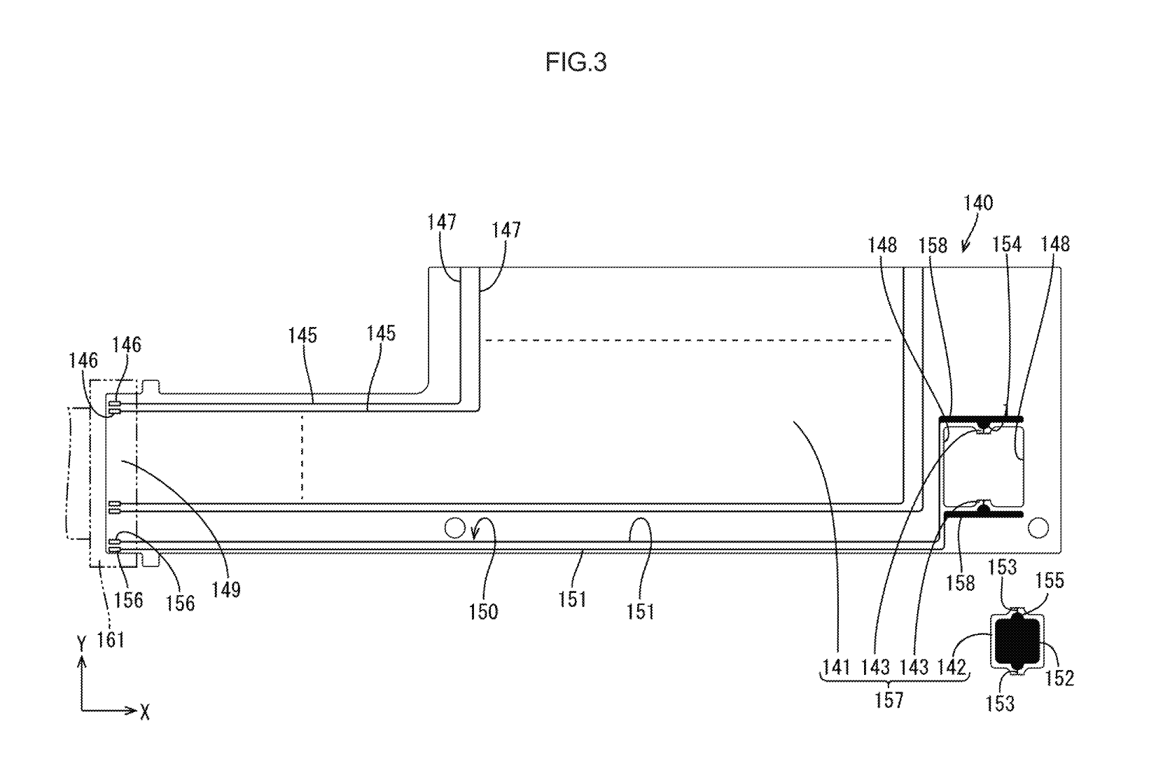

As illustrated in FIG. 2, the pair of weak portions 143, 143 sandwich the removable portion 142 from two sides thereof with respect to the Y-axis direction. Stress is concentrated on the weak portions 143 when an external force is applied to the removable portion 142 and strength is lower in the weak portions 143 than other portions. According to such a configuration, as illustrated in FIG. 3, the removable portion 142 can be separated from the board main body portion 141 by breaking the weak portions 143. The removable portion 142 has a substantially square plate shape and is between the two slits 148, 148. Namely, the removable portion 142 is surrounded by the board main body portion 141 over an entire periphery thereof. The lines 145, 150 disposed on the flexible circuit board 140 are covered with an insulation cover film such as a coverlay film (not illustrated) made of polyimide resin. However, it is preferable that the portions of the line 150 on the weak portions 143 (third conductive portion 153, which will be described later) are not covered with the coverlay film. According to such a configuration, the weak portions 143 are broken more easily.

The line 150 includes a pair of first conductive portions 151, 151 disposed on the board main body portion 141, a second conductive portion 152 disposed on the removable portion 142, and third conductive portions 153 connecting the respective first conductive portions 151 and the second conductive portion 152. The third conductive portion 153 has a line width (a length extending in the X-axis direction) that is smaller than a line width (a length extending in the X-axis direction) of a connection portion 154 of the first conductive portion 151 connected to the third conductive portion 153 and a line width (a length extending in the X-axis direction) of a connection portion 155 of the second conductive portion 152 connected to the third conductive potion 153. Namely, the third conductive portion 153 has a line width that is smaller than that of other surrounding portions and stress is likely to be concentrated on the third conductive portion 153. The line width here means a length extending in a direction perpendicular to an extending direction of the line 150. The first conductive portion 151 has an end portion 158 closer to the third conductive portion 153 and the end portion 158 has a line width that is greater than other portion of the first conductive portion 151.

The line 150 includes two end portions 156, 156 in a linear direction thereof and the two end portions 156, 156 are disposed on the board main body portion 141 and a part of the line 150 (the second conductive portion 152) between the two end portions 156, 156 is disposed on the removable portion 142. The second conductive portion 152 has a square shape that is slightly smaller than that of the removable portion 142. One end portions 146 of the liquid crystal panel lines 145 (end portions opposite from the liquid crystal panel 120 side, terminals) and the two end portions 156, 156 of the line 150 (terminals) are disposed on one edge portion 149 (a peripheral edge portion) of the board main body portion 141 in the longitudinal direction. The one end portions 146 and the end portions 156 are arranged in the Y-axis direction.

Next, a method of determining a board according to this embodiment will be described. In a process of producing the liquid crystal panel 120, a rework treatment may be performed for certain liquid crystal panels 120. Examples of the rework treatment include a high temperature aging treatment for replacing the polarizing plate 124 or discharging power from the liquid crystal panel 120. If such a rework treatment is performed, it is required to check whether the liquid crystal panel 120 is one that is subjected to the rework treatment or not in a succeeding step and the check result is required to be stored as a history. Accordingly, the liquid crystal panel 120 that has been subjected to the rework treatment can be specified during a manufacturing process or after shipping, and traceability of such a liquid crystal panel is ensured. In this embodiment, it can be determined whether the liquid crystal panel 120 is the one that has been subjected to the rework treatment or not by checking the flexible circuit board 140 included in the liquid crystal panel 120.

The method of determining a flexible circuit board 140 according to this embodiment includes a separation process and a determination process. After the rework treatment is performed to the flexible circuit board 140, the removable portion 142 is separated from the flexible circuit board 140 of the liquid crystal panel 120 by breaking the pair of weak portions 143, 143 as illustrated in FIG. 3 (a separation process). Namely, the separation process is performed on some specific flexible circuit boards 140 of the liquid crystal panels 120 (the flexible circuit boards 140). The pair of weak portions 143, 143 can be broken easily and therefore, the removable portion 142 can be separated from the flexible circuit board 140 by hand. Thus, the line 150 is disconnected by removing the second conductive portion 152 disposed on the removable portion 142.

In a checking process (the determination process) of checking the liquid crystal display device 110, a voltage is applied (a check signal is supplied) to the one end portions 146 of the liquid crystal panel lines 145 to activate and check the liquid crystal panel 120. As illustrated in FIG. 3, in the checking process, a voltage is applied to the two end portions 156, 156 of the line 150 at the same time of applying a voltage to the one end portions 146 and a current flowing through the line 150 is measured with a check connector 161 disposed overlapping the one edge portion 149 of the board main body portion 141.

A current flows through the line 150 if the removable portion 142 is not separated from the flexible circuit board as illustrated in FIG. 2. If the removable portion 142 is separated from the flexible circuit board, as illustrated in FIG. 3, the line 150 is disconnected and a current does not flow therethrough. Accordingly, for the liquid crystal panels 120 (the flexible circuit boards 140), it is determined whether the removable portion 142 is separated or not and it is determined whether the flexible circuit board 140 to be checked is the one that has been subjected to the rework treatment (a certain board) or not. Namely, the checking process has a function of the determination process of identifying the flexible circuit board 140. A determination result of the flexible circuit board 140 (whether or not the flexible circuit board 140 is the one that is subjected to the rework treatment) is stored in a storing portion of a checking device with a check result of the liquid crystal panel 120.

Next, advantageous effects of this embodiment will be described. In this embodiment, if a voltage is applied to the two end portions 156 of the line 150, a current flows through the line 150. If the removable portion 142 is separated from the board main body portion 141, a part of the line 150 (the second conductive portion 152) is removed from the line 150 and the line 150 is disconnected. With such a configuration, if a voltage is applied to the two end portions 156, 156 of the line 150, current does not flow through the line 150. Therefore, a current flowing through the line 150 is measured by applying a voltage to the two end portions 156, 156 of the line 150, and it is determined whether the removable portion 142 is separated or not. Based on the determination whether or not the removable portion 142 is separated, the flexible circuit boards 140 are distinguished between the ones that have been subjected to a rework treatment and the ones that have not been subjected to a rework treatment.

According to this embodiment, the separation of the removable portion 142 is not checked visually and therefore, determination accuracy is improved. Even if the removable portion 142 is covered with another component (such as a cover member covering the flexible circuit board 140), it can be determined whether the removable portion 142 is separated or not. Furthermore, the removable portion 142 that is continuous from the board main body portion 141 with the weak portions 143 can be easily separated by hand.

The board main body portion 141, the removable portion 142, and the weak portions 143 are formed from one plate member 157. The plate member 157 includes the two slits 148, 148 extending along a border between the board main body portion 141 and the removable portion 142. The weak portions 143 are a part of the plate member 157 that is between the two slits 148, 148. The weak portions 143 are formed easily by forming the slits 148 in the plate member 157.

The line 150 includes the pair of first conductive portions 151 disposed on the board main body portion 141, the second conductive portion 152 disposed on the removable portion 142, and the third conductive portions 153 connecting the respective first conductive portions 151 and the second conductive portion 152. The line width of the third conductive portion 153 is smaller than the line width of the connection portion 154 of the first conductive portion 151 connected to the third conductive portion 153 and the line width of the connection portion 155 of the second conductive portion 152 connected to the third conductive potion 153. The stress is likely to be concentrated on the third conductive portions that have a relatively smaller line width. Accordingly, the third conducive portions 153 are easily broken when separating the removable portion 142.

The removable portion 142 is surrounded by the board main body portion 141 over an entire periphery thereof. According to such a configuration, an external force is less likely to act on the removable portion 142. As a result, the removable portion 142 is less likely to be separated unintentionally.

The weak portions 143 are provided to sandwich the removable portion 142. In the separation process, the removable portion 142 is rotated around an axis along the pair of weak portions 143, 143 (an axis along the Y-axis direction in FIG. 2) as a rotation axis such that the weak portions 143, 143 are twisted to be broken. Accordingly, the removable portion 142 is easily separated.

The liquid crystal display device 110 of this embodiment includes the flexible circuit board 140 and the liquid crystal panel 120. The liquid crystal panel lines 145 that are electrically connected to the liquid crystal panel 120 are disposed on the board main body portion 141. The one end portions 146 of the liquid crystal panel lines 145 and the two end portions 156, 156 of the line 150 are disposed on the one edge portion 149 of the board main body portion 141. According to such a configuration, in the checking process of checking the liquid crystal display device 110, a voltage is applied to the two end portions 156, 156 of the line 150 at the same time of applying a voltage to the one end portions 146 of the liquid crystal panel lines 145 and it is determined whether the removable portion 142 is separated or not with the check connector 161. Thus, the determination process is performed at the same time of the checking process such that the time required for identifying the flexible circuit board 140 is reduced. Furthermore, the determination process is performed at the same time of the checking process and therefore, the determination process is performed surely.

### Second Embodiment

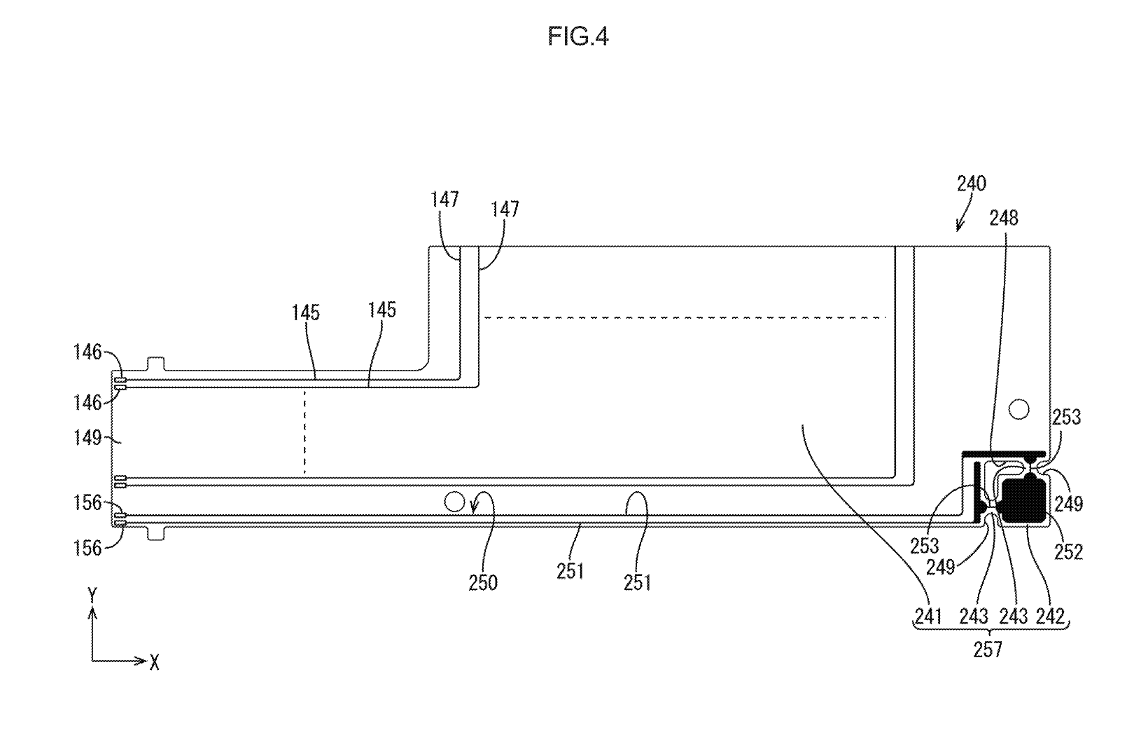

A second embodiment of the technology described herein will be described with reference to FIG. 4. The same parts as those of the above embodiment are provided with the same symbols or numbers and will not be described. A flexible circuit board 240 of this embodiment includes a slit 248 having an L-shape and two slits 249, 249 that are open at a peripheral edge of a plate member 257 (a plate member including a board main body portion 241, a removable portion 242, and weak portions 243). The removable portion 242 is continuous from the board main body portion 241 via the pair of weak portions 243, 243 and the weak portions 243, 243 extend in directions that are perpendicular to each other. According to such a configuration, the removable portion 242 is disposed at a corner of the plate member 257. A line 250 includes a pair of first conductive portions 251, 251, a second conductive portion 252 disposed on the removable portion 242, and third conductive potions 253 that connect the respective first conductive portions 251 and the second conductive portion 252. According to the configuration including the removable portion 242 at the corner of the plate member 257, the removable portion 242 can be easily held and easily separated from the board main body portion 241.

### Third Embodiment

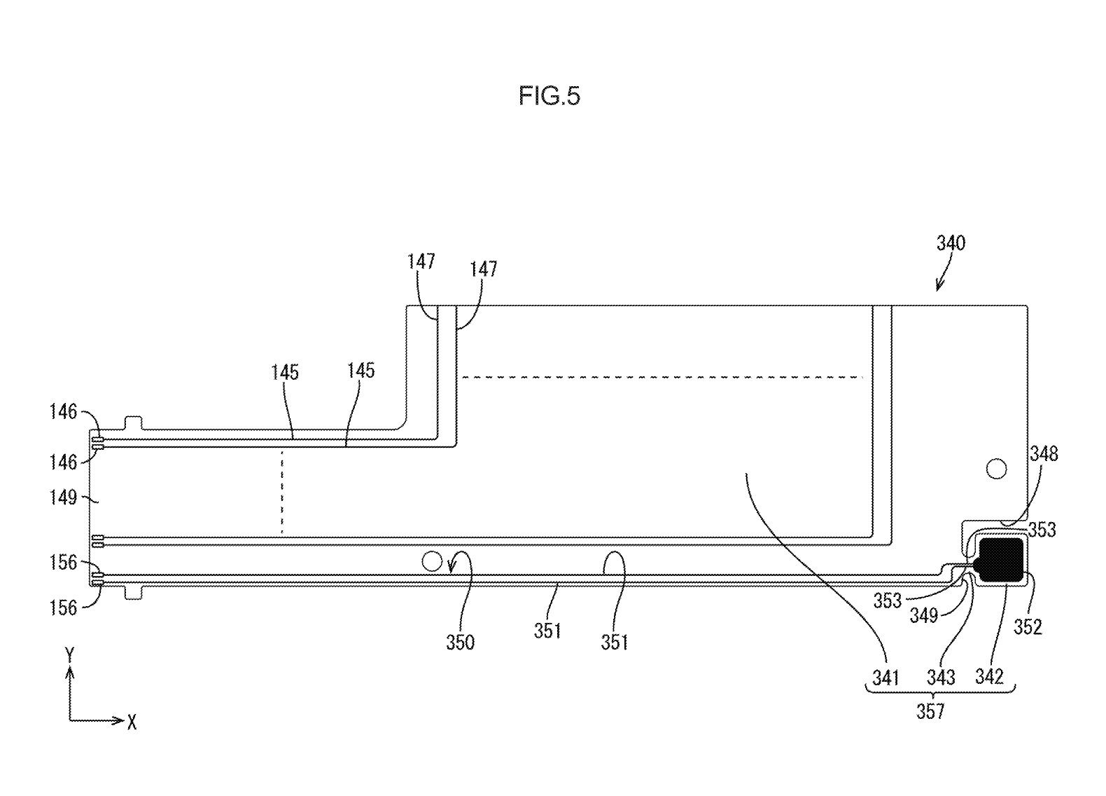

Next, a third embodiment of the technology described herein will be described with reference to FIG. 5. The same parts as those of the above embodiment are provided with the same symbols or numbers and will not be described. A flexible circuit board 340 of this embodiment includes a slit 348 having an L-shape and opening at a peripheral edge of a plate member 357 (a plate member including a board main body portion 341, a removable portion 342, and a weak portion 343) and a slit 349 that is open at a peripheral edge of the plate member 357. The removable portion 342 is continuous from the board main body portion 341 in a cantilever state. A line 350 includes a pair of first conductive portions 351, 351, a second conductive portion 352 disposed on the removable portion 342, and third conductive potions 353 that connect the respective first conductive portions 351 and the second conductive portion 352. In this embodiment, two third conductive portions 353 are disposed on the one weak portion 343.

### Other Embodiments

The technology described herein is not limited to the embodiments, which have been described using the foregoing descriptions and the drawings. For example, embodiments described below are also included in the technical scope.

(1) The above embodiments include the flexible circuit board that is connected to the liquid crystal panel as the board. However, it is not limited thereto. For example, the board may be a rigid circuit board. The above embodiments include the liquid crystal display device as the electric device. However, it is not limited thereto. For example, the electric device may be a lighting device such as a backlight, a vehicular headlight, or a lighting device, various kinds of sensors such as a temperature and humidity sensor, an acceleration sensor, a transmission sensor, or a camera sensor (a CCD sensor or a CMOS sensor), and switches. A board used in each of such electric devices is also included in the technical scope.

(2) In the above embodiments, liquid crystal panels of a transmission type, a semi-transmission type, or a reflection type, or a liquid crystal panel including memory liquid crystals may be used. The above embodiments include the liquid crystal panel as the display panel. However, it is not limited thereto. An organic EL display panel or a LED display panel may be used as the display panel.

(3) In the above embodiments, the weak portions are provided by forming the slits. However, it is not limited thereto. The weak portions may be at least configured such that stress is concentrated thereon to break the weak portions. For example, the weak portions may be configured by forming a groove between the board main body and the removable portion.

(4) In the separation process, the removable portion 142 is separated from the flexible circuit board 140 of the liquid crystal panel 120 that has been subjected to a rework treatment. Accordingly, the flexible circuit board 140 that has been subjected to the rework treatment is distinguished from the one that has not been subjected to the rework treatment. However, it is not limited thereto. For example, the removable portion 142 may be separated from the flexible circuit board 140 of the liquid crystal panel 120 that has not been subjected to the rework treatment. In the above embodiments, it is determined whether the rework treatment has been performed or not based on the determination whether the removable portion 142 is separated or not. A type of treatment used for determining whether or not the removable portion 142 is separated may not be limited to the rework treatment.

(5) In the above embodiment, the two first conductive portions 151, 151 are arranged parallel to each other. However, it is not limited thereto. For example, the first conductive portion 151, the second conductive portion 152, the first conductive portion 151 may be arranged linearly in this order.

(6) The liquid crystal panel 120 may not include the driver 131.

(7) The connection structure of the board main body portion and the removable portion is not limited to that described in each of the above embodiments.

(8) In the above embodiments, the checking process of checking the liquid crystal panel 120 also has a function of the determination process of identifying the flexible circuit board 140. However, it is not limited thereto. The determination process may be performed at a different timing from the checking process.

(9) In the above embodiments, multiple sets of the configurations for identifying the boards (the line for identifying a board, the removable portion, and the weak portions) may be included. For example, in a configuration including two removable portions, each of the removable portions is used for determining whether corresponding one of two different treatments is performed. In a configuration including multiple removable portions, the number of determination patterns is 2 to the Nth power if the number of the removable portions is N.

1. A board comprising:
a board main body portion;
a removable portion that is removably continuous from the board main body portion via a weak portion having strength lower than a surrounding portion thereof; and
a line having two end portions in a linear direction on the board main body portion and a portion between the two end portions on the removable portion.

2. The board according to claim 1, wherein
the board main body portion, the removable portion, and the weak portion are formed from a plate member,
the plate member includes at least two slits extending along a border between the board main body portion and the removable portion, and
the weak portion is a portion of the plate member between the at least two slits.

3. The board according to claim 1, wherein
the line includes a pair of first conductive portions disposed on the board main body portion, a second conductive portion disposed on the removable portion, and a third conductive portion disposed on the weak portion and connecting the first conductive portions and the second conductive portion, and
the third conductive portion has a line width that is smaller than a line width of a connecting portion of one of the first conductive portions and the third conductive portion and a line width of a connecting portion of the second conductive portion and the third conductive portion.

4. The board according to claim 1, wherein the removable portion is surrounded by the board main body portion over an entire periphery thereof.

5. The board according to claim 1, wherein the weak portion includes a pair of weak portions that sandwiches the removable portion therebetween.

6. An electric device comprising:
the board according to claim 1; and
an electric component, wherein
the board main body portion includes an electric component line that is electrically connected to the electric component, and
the electric component line has an end portion opposite from the electric component and the end portion of the electric component line and two end portions of the line are disposed on a peripheral edge portion of the board main body portion.

7. The electric device according to claim 6, wherein the electric component is a display panel displaying an image.

8. A method of determining a certain board, the method comprising:
a separation process of breaking a weak portion of the certain board and separating a removable portion from a board main body portion of the certain board, the removable portion being removably continuous from the board main body portion via the weak portion having strength lower than a surrounding portion thereof, the board main body portion having two end portions of a line in a linear direction thereof, and the removable portion having a part of the line between the two end portions; and
a determining process of determining whether the removable portion is separated or not by applying a voltage to the two end portions of the line of the certain board.
